(19) United States
(12) Patent Application Publication
(10) Pub. No.: US 2025/0072237 A1
(43) Pub. Date: Feb. 27, 2025

(54) Display Device and Display Panel

(71) Applicant: LG Display Co., Ltd., Seoul (KR)

(72) Inventor: Uisu Sin, Paju-si (KR)

(21) Appl. No.: 18/657,626

(22) Filed: May 7, 2024

(30) Foreign Application Priority Data
Aug. 21, 2023 (KR) 10-2023-0109353

(51) Int. Cl. H10K 59/131; G09G 3/3266; G09G 3/3275

(52) U.S. Cl. CPC H10K 59/131; G09G 3/3266; G09G 3/3275; G09G 2320/0209

(57) ABSTRACT

A display device may include a substrate including an active area on which a plurality of subpixels are arranged and a non-active area including a pad area located in a column direction from the active area, a plurality of gate lines disposed in the active area and each extending in a row direction, a plurality of data lines disposed in the active area and each extending in the column direction, a plurality of pads disposed in the pad area, and a plurality of link lines electrically connecting the plurality of pads and the plurality of data lines. Each of the plurality of link lines may include a row-direction link line part extending in the row direction and a column-direction link line part extending in the column direction. The row-direction link line parts included in each of the plurality of link lines may have lengths corresponding to each other.

### CROSS REFERENCE TO RELATED APPLICATION

This application claims priority from Republic of Korea Patent Application No. 10-2023-0109353, filed on Aug. 21, 2023, which is hereby incorporated by reference in its entirety.

### TECHNICAL FIELD

Embodiments of the present disclosure relate to a display device and a display panel.

### BACKGROUND

A display panel of a display device may include an active area where an image is displayed and a non-active area where an image is not displayed. Since there may be disposed various structures, circuits, and lines in the non-active area (also referred to as a non-display area or bezel) of the display panel, it is not easy to reduce a bezel of the display panel. In particular, there may be not easy to reduce the bezel since link lines for transmitting data signals to data lines are arranged in the non-active area of the display panel.

### SUMMARY

Embodiments of the present disclosure may provide a display device and a display panel having a data link structure for reducing the bezel.

Embodiments of the present disclosure may provide a display device and a display panel with a data link structure capable of reducing crosstalk deviation between a link line and a gate line.

Embodiments of the present disclosure may provide a display device and a display panel with a data link structure capable of reducing the bezel and a horizontal crosstalk deviation.

Embodiments of the present disclosure may provide a display device and a display panel having a data link structure in which a data line and a link line are connected within an active area.

Embodiments of the present disclosure may provide a display device and a display panel having a data link structure in which each of a plurality of link lines in the active area has the same overlapping area with a gate line.

A display device according to embodiments of the present disclosure may include a substrate including an active area on which a plurality of subpixels are arranged and a non-active area including a pad area located in a column direction from the active area, a plurality of gate lines disposed in the active area and each extending in a row direction, a plurality of data lines disposed in the active area and each extending in the column direction, a plurality of pads disposed in the pad area, and a plurality of link lines electrically connecting the plurality of pads and the plurality of data lines.

Each of the plurality of link lines may include a row-direction link line part extending in the row direction and a column-direction link line part extending in the column direction.

The row-direction link line part included in each of the plurality of link lines may be disposed in the active area, and at least a portion of the column-direction link line part included in each of the plurality of link line may be disposed in the active area.

The row-direction link line part included in each of the plurality of link lines may vertically overlap with at least one gate line among the plurality of gate lines.

the row-direction link line parts included in each of the plurality of link lines may have lengths corresponding to each other.

The overlapping areas of the row-direction link line parts included in each of the plurality of link lines and at least one gate line may be the same.

The plurality of data lines may include a first data line and a second data line, and the plurality of pads may include a first pad and a second pad. The plurality of link lines may include a first link line electrically connecting the first data line and the first pad and a second link line electrically connecting the second data line and the second pad.

The first link line may include a first row-directtion link line part and a first column-direction link line part. The first row-direction link line part may electrically connect the first data line and the first column-direction link line part. The first column-direction link line part may electrically connect the first row-direction link line part and the first pad.

The second link line may include a second row-directtion link line part and a second column-direction link line part. The second row-direction link line part may electrically connect the second data line and the second column-direction link line part. The second column-direction link line part may electrically connect the second row-direction link line part and the second pad.

The first row-direction link line part and the second row-direction link line part may have the same length.

The display device may further include a first data line connection hole through which the first data line and the first row-direction link line part are connected, a first link line connection hole through which the first row-direction link line part and the first column-direction link line part are connected, a second data line connection hole through which the second data line and the second row-direction link line part are connected, and a second link line connection hole through which the second row-direction link line part and the second column-direction link line part are connected.

The imaginary line connecting the first data line connection hole, the first link line connection hole, the second link line connection hole and the second data line connection hole may include corners of a parallelogram or trapezoid.

A display device according to embodiments of the present disclosure may include a substrate including an active area on which a plurality of subpixels are arranged and a non-active area including a pad area located in a column direction from the active area, a plurality of pads disposed in a pad area, a plurality of data lines arranged in the active area and each extending in a column direction, and a plurality of link lines electrically connecting the plurality of pads and the plurality of data lines.

The plurality of data lines may include a first data line and a second data line, and the plurality of pads may include a first pad and a second pad.

The plurality of link lines may include a first link line electrically connecting a first data line located on the outer side among the first data line and the second data line with a first pad located on the outer side among the first pad and the second pad, and a second link line electrically connecting the second data line located further inside among the first data line and the second data line to the second pad located further inside among the first pad and the second pad.

Each of the first link line and the second link line may include a portion disposed in the active area.

According to the embodiments of the present disclosure, there may provide a display device and a display panel having data a link structure for reducing the bezel.

According to the embodiments of the present disclosure, there may provide a display device and a display panel with a data link structure capable of reducing crosstalk deviation between a link line and a gate line.

According to the embodiments of the present disclosure, there may provide a display device and a display panel with a data link structure capable of reducing the bezel and a horizontal crosstalk deviation.

According to the embodiments of the present disclosure, it is possible to reduce the weight of the display panel and a display device by reducing the bezel through the data link structure.

### BRIEF DESCRIPTION OF THE DRAWINGS

FIG. 1 illustrates a system configuration diagram of a display device according to embodiments of the present disclosure.

FIG. 2 illustrates a display panel according to embodiments of the present disclosure.

FIG. 3 illustrates a substrate of a display panel according to embodiments of the present disclosure.

FIG. 4 illustrates a data link structure in a display panel according to embodiments of the present disclosure.

FIG. 5 illustrates a data link structure for bezel reduction in a display panel according to embodiments of the present disclosure.

FIGS. 6 and 7 illustrate a data link structure for reducing bezels and reducing horizontal crosstalk deviation in a display panel according to embodiments of the present disclosure.

FIG. 8 is a plan view of a partial area of the display panel of FIG. 6 or FIG. 7 according to embodiments of the present disclosure.

FIG. 9 is a cross-sectional view taken along line A-A′ of FIG. 8 according to embodiments of the present disclosure.

FIG. 10 is a cross-sectional view taken along line B-B′ of FIG. 8 according to embodiments of the present disclosure.

FIG. 11 is a cross-sectional view taken along line C-C′ of FIG. 8 according to embodiments of the present disclosure.

FIG. 12 illustrates a data signal transmitted to a data line according to a data link structure for bezel reduction according to embodiments of the present disclosure.

FIG. 13 illustrates a data signal transmitted to a data line according to a data link structure for reducing the bezel and horizontal crosstalk deviation according to embodiments of the present disclosure.

### DETAILED DESCRIPTION

Hereinafter, embodiments of the disclosure are described in detail with reference to the accompanying drawings. In assigning reference numerals to components of each drawing, the same components may be assigned the same numerals even when they are shown on different drawings. When determined to make the subject matter of the disclosure unclear, the detailed of the known art or functions may be skipped. As used herein, when a component “includes,” “has,” or “is composed of” another component, the component may add other components unless the component “only” includes, has, or is composed of' the other component. As used herein, the singular forms “a”, “an” and “the” are intended to include the plural forms as well, unless the context clearly indicates otherwise.

Such denotations as “first,” “second,” “A,” “B,” “(a),” and “(b),” may be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components may be directly “connected”, “coupled” or “linked” , or another component may intervene. Here, the other component may be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it may include a non-continuous relationship unless the term “immediately” or “directly” is used.

When a component is designated with a value or its corresponding information (e.g., level), the value or the corresponding information may be interpreted as including a tolerance that may arise due to various factors (e.g., process factors, internal or external impacts, or noise).

Hereinafter, various embodiments of the disclosure are described in detail with reference to the accompanying drawings.

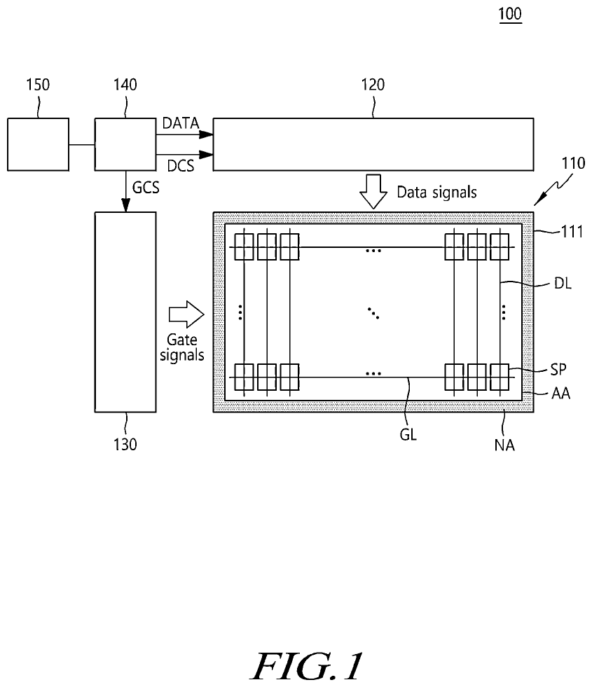

FIG. 1 illustrates a system configuration diagram of a display device 100 according to embodiments of the present disclosure.

Referring to FIG. 1, a display device 100 according to embodiments of the present disclosure may include a display panel 110 and a display driving circuit as components for displaying an image. The display driving circuit may be a circuit for driving the display panel 110, and may include a data driving circuit 120, a gate driving circuit 130, and a controller 140.

The display panel 110 may include a substrate 111 and a plurality of subpixels SP disposed on the substrate 111.

The substrate 111 may include an active area AA capable of displaying an image and a non-active area NA located outside the active area AA. A plurality of subpixels SP for image display may be disposed in the active area AA. The non-active area NA may include a pad area PA located in a first direction (e.g., column direction or row direction) from the active area AA.

In the display panel 110 according to embodiments of the present disclosure, the non-active area NA may be very small. In this specification, the non-active area NA may be also referred to as “a bezel.” For example, the non-active area NA may include a first non-active area located outside the active area AA in a first direction, a second non-active area located outside the active area AA in a second direction, a third non-active area located outside the active area AA in a direction opposite to the first direction, and a fourth non-active area located outside the active area AA in the direction opposite to the second direction. Among the first to fourth non-active areas, the first non-active area may include a pad area to which the driving circuit is connected or bonded. Among the first to fourth non-active areas, the second to fourth non-active areas which do not include a pad area may have a very small size.

For another example, a boundary area between the active area AA and the non-active area NA may be bent so that the non-active area NA may be located below the active area AA. In this case, when the user looks at the display device 100 from the front, there may be little or no non-active area NA visible to the user.

There may be disposed various types of signal lines for driving a plurality of subpixels SP on the substrate 111 of the display panel 110.

The display device 100 according to embodiments of the present disclosure may be a liquid crystal display device or the like, or may be a self-luminous display device in which the display panel 110 emits light by itself. In the case that the display device 100 according to embodiments of the present disclosure is a self-luminous display device, each of the plurality of subpixels SP may include a light emitting device.

For example, the display device 100 according to embodiments of the present disclosure may be an organic light emitting display device in which a light emitting device is implemented as an organic light emitting diode (OLED). For another example, the display device 100 according to embodiments of the present disclosure may be an inorganic light emitting display device in which the light emitting device is implemented as an inorganic-based light emitting diode. For another example, the display device 100 according to embodiments of the present disclosure may be a quantum dot display device in which a light emitting device is implemented with quantum dots, which are semiconductor crystals emitting light on their own.

A structure of each of the plurality of subpixels SP may vary depending on the type of the display device 100. For example, if the display device 100 is a self-luminous display device in which subpixels SP emit light by themselves, each subpixel SP may include a light emitting device emitting light by itself, one or more transistors, and one or more capacitors.

For example, various types of signal lines may include a plurality of data lines DL carrying data signals (also referred to as data voltages or image signals) and plurality of gate lines GL carrying gate signals (also referred to as scan signals)

For example, a plurality of data lines DL and a plurality of gate lines GL may cross each other. Each of the plurality of data lines DL may be arranged to extend in a first direction, and each of the plurality of gate lines GL may be arranged to extend in a second direction. Here, the first direction may be a column direction and the second direction may be a row direction. Alternatively, the first direction may be a row direction and the second direction may be a column direction. Hereinafter, for convenience of explanation, it will be exemplified a case in which each of the plurality of data lines DL is arranged in a column direction, and each of the plurality of gate lines GL is arranged in a row direction.

The data driving circuit 120 may be a circuit for driving a plurality of data lines DL, and may output data signals to the plurality of data lines DL.

The data driving circuit 120 may receive image data DATA in digital form from the controller 140, convert the received image data DATA into data signals in analog form, and output the data signals to the plurality of data lines DL.

For example, the data driving circuit 120 may be connected to the display panel 110 using a tape automated bonding (TAB) method, or may be connected to a bonding pad of the display panel 110 using a chip-on-glass (COG) or a chip-on-panel (COP) method, or may be implemented using a chip-on-film (COF) method and connected to the display panel 110.

The data driving circuit 120 may be connected to one side (e.g., an upper or lower side) of the display panel 110. Alternatively, depending on the driving method, panel design method, etc., the data driving circuit 120 may be connected to both sides (e.g., upper and lower sides) of the display panel 110, or may be connected to two or more of the four sides of the display panel 110.

The data driving circuit 120 may be connected to the outside of the active area AA of the display panel 110, but alternatively, it may be disposed in the active area AA of the display panel 110.

The gate driving circuit 130 may be a circuit for driving a plurality of gate lines GL and may output gate signals to the plurality of gate lines GL.

The gate driving circuit 130 may receive a first gate voltage corresponding to the turn-on level voltage and a second gate voltage corresponding to the turn-off level voltage along with various gate driving control signals GCS, generate gate signals and supply the generated gate signals to a plurality of gate lines GL.

In the display device 100 according to embodiments of the present disclosure, the gate driving circuit 130 may be built or embedded into the display panel 110 as a gate-in-panel (GIP) type. If the gate driving circuit 130 is a gate-in-panel type, the gate driving circuit 130 may be formed on the substrate 111 of the display panel 110 during the manufacturing process of the display panel 110.

For example, the gate driving circuit 130 may be disposed in the non-active area NA of the display panel 110.

As another example, the gate driving circuit 130 may be disposed in the active area AA of the display panel 110. In this case, as an example, the gate driving circuit 130 may be disposed in a first partial area within the active area AA (e.g., a left area or a right area within the active area AA). As another example, the gate driving circuit 130 may be disposed in a first partial area within the active area AA (e.g., a left area or a right area within the active area AA) and a second partial area (e.g., a right area or left area within the active area AA).

In the present disclosure, a gate driving circuit 130 built into the display panel 110 by the gate-in-panel type may also be referred to as a “gate-in-panel circuit.”

The controller 140 may be a device for controlling the data driving circuit 120 and the gate driving circuit 130, and may control the driving timing for the plurality of data lines DL and the driving timing for the plurality of gate lines GL.

The controller 140 may supply a data driving control signal DCS to the data driving circuit 120 to control the data driving circuit 120, and may supply a gate driving control signal GCS to the gate driving circuit 130 to control the gate driving circuit 130.

The controller 140 may receive input image data from a host system 150 and supply image data DATA to the data driving circuit 120 based on the input image data.

The controller 140 may be implemented as a separate component from the data driving circuit 120, or may be integrated with the data driving circuit 120 and implemented as an integrated circuit.

The controller 140 may be a timing controller used in typical display technology, or may be a control device including a timing controller for further performing other control functions, or may be a control device other than a timing controller, or may be a circuit within a control device. The controller 140 may be implemented with various circuits or electronic components, such as an integrated circuit (IC), a field programmable gate array (FPGA), an application specific integrated circuit (ASIC), or a processor.

The controller 140 may be mounted on a printed circuit board, a flexible printed circuit, etc., and may be electrically connected to the data driving circuit 120 and the gate driving circuit 130 through a printed circuit board, a flexible printed circuit, etc.

The controller 140 may transmit and receive signals with the data driving circuit 120 according to one or more predetermined interfaces. For example, the interface may include a low voltage differential signaling (LVDS) interface, an embedded clock point-point interface (EPI) interface, a serial peripheral interface (SPI), etc.

In order to provide not only an image display function but also a touch sensing function, the display device 100 according to embodiments of the present disclosure may may include a touch sensor and a touch sensing circuit which senses the touch sensor to detect an occurrence of touch by a touch object such as a finger or a pen or to detect a touch position.

The touch sensing circuit may include a touch driving circuit which drives and senses the touch sensor to generate and output touch sensing data, and a touch controller capable of detecting the occurrence of a touch or detecting the touch position using touch sensing data.

The touch sensor may include a plurality of touch electrodes. The touch sensor may further include a plurality of touch lines to electrically connect a plurality of touch electrodes and a touch driving circuit.

The touch sensor may be disposed outside the display panel 110 in the form of a touch panel or may be disposed inside the display panel 110. If the touch sensor exists outside the display panel 110 in the form of a touch panel, the touch sensor is said to be an external type. If the touch sensor is an external type, the touch panel and the display panel 110 may be manufactured separately and combined during the assembly process. The external touch panel may include a touch panel substrate and a plurality of touch electrodes on the touch panel substrate.

If the touch sensor is disposed inside the display panel 110, the touch sensor may be formed on the substrate along with signal lines and electrodes related to display driving during the manufacturing process of the display panel 110.

The touch driving circuit may supply a touch driving signal to at least one of the plurality of touch electrodes and generate touch sensing data by sensing at least one of the plurality of touch electrodes.

The touch sensing circuit may perform touch sensing using a self-capacitance sensing method or a mutual-capacitance sensing method.

If the touch sensing circuit performs touch sensing using the self-capacitance sensing method, the touch sensing circuit may perform touch sensing based on the capacitance between each touch electrode and the touch object (e.g., finger, pen, etc.). According to the self-capacitance sensing method, each of the plurality of touch electrodes may serve as a driving touch electrode and a sensing touch electrode. The touch driving circuit may drive all or part of the plurality of touch electrodes and sense all or part of the plurality of touch electrodes.

In the case that the touch sensing circuit performs touch sensing using the mutual-capacitance sensing method, the touch sensing circuit may perform touch sensing based on the capacitance between touch electrodes. According to the mutual-capacitance sensing method, the plurality of touch electrodes may be divided into driving touch electrodes and sensing touch electrodes. The touch driving circuit may drive driving touch electrodes and sense sensing touch electrodes.

The touch driving circuit and touch controller included in the touch sensing circuit may be implemented as separate devices or as one device. Additionally, the touch driving circuit and the data driving circuit may be implemented as separate devices or as one device.

The display device 100 may further include a power supply circuit which supplies various types of power to the display driving circuit and/or the touch sensing circuit.

The display device 100 according to embodiments of the present disclosure may be a mobile terminal such as a smart phone or tablet, or a monitor or television (TV) of various sizes, but is not limited thereto, and may be a display of various types and sizes capable of displaying information or images.

The display device 100 according to embodiments of the present disclosure may further include an electronic device such as a camera (or image sensor) and a detection sensor. For example, the detection sensor may be a sensor capable of detecting an object or a human body by receiving light such as infrared, ultrasonic, or ultraviolet rays.

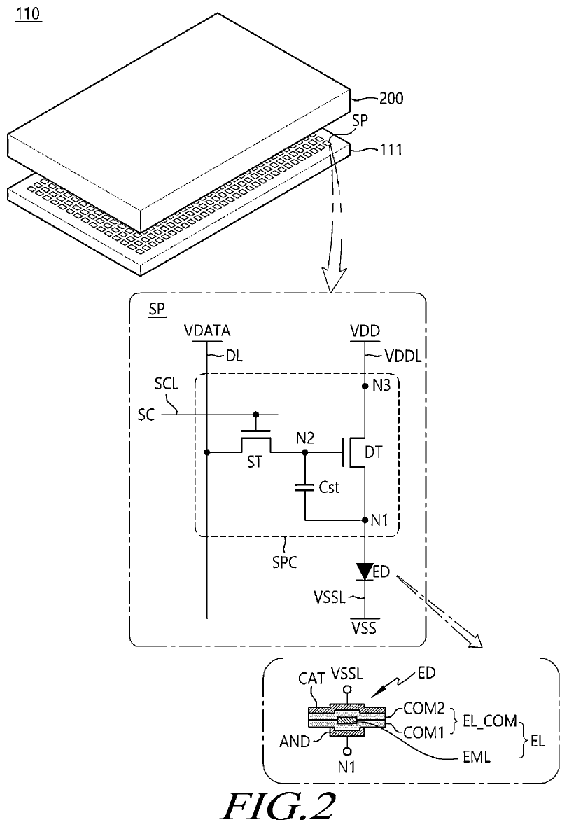

FIG. 2 illustrates a display panel 110 according to embodiments of the present disclosure.

Referring to FIG. 2, the display panel 110 may include a substrate 111 on which a plurality of subpixels SP are disposed and an encapsulation layer 200 on the substrate 111. Here, the encapsulation layer 200 may also be referred to as an encapsulation substrate or an encapsulation part.

Referring to FIG. 2, in the case that the display device 100 according to embodiments of the present disclosure is a self-luminous display device, each of the plurality of subpixels SP disposed on the substrate 111 may include a light emitting device ED and a subpixel circuit SPC for driving the light emitting device ED.

Referring to FIG. 2, the subpixel circuit SPC may include a plurality of pixel driving transistors for driving the light emitting device ED and at least one capacitor. In the present disclosure, the subpixel circuit SPC may drive the light emitting device ED by supplying a driving current to the light emitting device ED at a predetermined timing. The light emitting device ED may be driven by a driving current to emit light.

The plurality of pixel driving transistors may include a driving transistor DT for driving the light emitting device ED and a scan transistor ST which is turned on or off depending on the scan signal SC.

The driving transistor DT may supply driving current to the light emitting device ED.

The scan transistor ST may be configured to control the electrical state of a corresponding node in the subpixel circuit SPC or to control the state or operation of the driving transistor DT.

At least one capacitor may include a storage capacitor Cst to maintain a constant voltage during a frame.

For driving the subpixel SP, a data signal VDATA which is an image signal, and a scan signal SC which is a gate signal may be applied to the subpixel SP. Additionally, a common pixel driving voltage including a first common driving voltage VDD and a second common driving voltage VSS may be applied to the subpixel SP.

The light emitting device ED may include an anode AND, a light emitting device intermediate layer EL, and a cathode CAT. The light emitting device intermediate layer EL may be disposed between the anode AND and the cathode CAT.

In the case that the light emitting device ED is an organic light emitting device, the light emitting device intermediate layer EL may include an emission layer EML, a first common intermediate layer COM1 between the anode AND and the emission layer EML, and a second common intermediate layer COM2 between the emission layer EML and the cathode CAT. The emission layer EML may be disposed in each subpixel SP. In addition, the first common intermediate layer COM1 and the second common intermediate layer COM2 may be commonly disposed across a plurality of subpixels SP. The emission layer EML may be disposed in each emission area, and the first common intermediate layer COM1 and the second common intermediate layer COM2 may be commonly disposed over a plurality of emission areas and non-emission areas. The first common intermediate layer COM1 and the second common intermediate layer COM2 may be collectively referred to as a common intermediate layer EL_COM.

For example, the first common intermediate layer COM1 may include a hole injection layer HIL and a hole transfer layer HTL. The second common intermediate layer COM2 may include an electron transport layer ETL and an electron injection layer EIL. The hole injection layer may inject holes from the anode AND to the hole transport layer, the hole transport layer may transport holes to the emission layer EML, and the electron injection layer may inject electrons from the cathode CAT to the electron transport layer, and the electron transport layer may transport electrons to the emission layer (EML).

For example, the cathode CAT may be electrically connected to a second common driving voltage line VSSL. The second common driving voltage VSS, which is a type of common pixel driving voltage, may be applied to the cathode CAT through the second common driving voltage line VSSL. The anode AND may be electrically connected to a first node N1 of the driving transistor DT of each subpixel SP. In the present disclosure, the second common driving voltage VSS may also be referred to as a base voltage VSS, and the second common driving voltage line VSSL may also be referred to as a base voltage line.

For example, the anode AND may be a pixel electrode disposed in each subpixel SP, and the cathode CAT may be a common electrode commonly disposed in a plurality of subpixels SP. As another example, the cathode CAT may be a pixel electrode disposed in each subpixel SP, and the anode AND may be a common electrode commonly disposed in a plurality of subpixels SP. Hereinafter, for convenience of explanation, it is assumed that the anode AND is a pixel electrode and the cathode CAT is a common electrode.

Each light emitting device ED may be composed of overlapping parts of an anode AND, a light emitting device intermediate layer EL and a cathode CAT. A predetermined emission area may be formed by each light emitting element ED. For example, the emission area of each light emitting device ED may include an area where the anode AND, the light emitting device intermediate layer EL and the cathode CAT overlap.

For example, the light emitting device ED may be an organic light emitting diode (OLED), an inorganic light emitting diode (LED: light emitting diode), or a quantum dot light emitting device, etc. For example, if the light emitting device ED is an organic light emitting diode (OLED), the light emitting device intermediate layer EL in the light emitting device ED may include a light emitting device intermediate layer EL containing an organic material.

The driving transistor DT may be a driving transistor for supplying driving current to the light emitting device ED. The driving transistor DT may be connected between the first common driving voltage line VDDL and the light emitting device ED.

The driving transistor DT may include a first node NI electrically connected to the light emitting device ED, a second node N2 to which the data signal (VDATA) can be applied, and a third node N3 to which the driving voltage VDD is applied from the driving voltage line DVL.

In the driving transistor DT, the second node N2 may be a gate node, the first node N1 may be a source node or a drain node, and the third node N3 may be a drain node or a source node. Hereinafter, for convenience of explanation, it will be exemplified a case, the second node N2 is a gate node, the first node N1 is a source node, and the third node N3 is a drain node in the driving transistor DT.

The scan transistor ST included in the subpixel circuit SPC illustrated in FIG. 2 may be a switching transistor for transmitting a data signal VDATA which is an image signal to the second node N2 as the gate node of the driving transistor DT.

The scan transistor ST may be controlled on-off by the scan signal SC which is a gate signal applied through the scan line SCL as a type of gate line GL, and may control the electrical connection between the second node N2 of the driving transistor DT and the data line DL. A drain electrode or source electrode of the scan transistor ST may be electrically connected to the data line DL, and a source electrode or drain electrode of the scan transistor ST may be electrically connected to the second node N2 of the driving transistor DT, and the gate electrode of the scan transistor ST may be electrically connected to the scan line SCL.

The storage capacitor Cst may be electrically connected between the first node N1 and the second node N2 of the driving transistor DT. The storage capacitor Cst may include a first capacitor electrode which is electrically connected to the first node NI of the driving transistor (DT) or corresponds to the first node N1 of the driving transistor DT, and a second capacitor electrode which is electrically connected to the second node N2 of the driving transistor DT or corresponds to the second node N2 of the driving transistor DT.

The storage capacitor Cst may be an external capacitor intentionally designed outside the driving transistor DT rather than a parasitic capacitor (e.g., Cgs, Cgd) as an internal capacitor which may exist between the first node N1 and the second node N2 of the driving transistor DT.

Each of the driving transistor DT and scan transistor ST may be an n-type transistor or a p-type transistor.

The display panel 110 may have a top emission structure or a bottom emission structure.

If the display panel 110 has a top emission structure, at least a portion of the subpixel circuit SPC may overlap with at least a portion of the light emitting device ED in a vertical direction. Alternatively, if the display panel 110 has a bottom emission structure, the subpixel circuit SPC may not overlap the light emitting device ED in the vertical direction.

The subpixel circuit SPC may have a 2T (Transistor)-1C (Capacitor) structure including two transistors DT and ST and one capacitor Cst, as shown in FIG. 2. Alternatively, the subpixel circuit SPC may further include one or more transistors or one or more capacitors.

For example, the subpixel circuit SPC may have an 8T-1C structure including eight transistors and one capacitor. For another example, the subpixel circuit SPC may have a 6T-2C structure including six transistors and two capacitors. As another example, the subpixel circuit SPC may have a 7T-1C structure including seven transistors and one capacitor. As another example, a subpixel circuit SPC may have an 8T-1C structure including eight transistors and one capacitor.

Depending on the structure of the subpixel circuit SPC, there may vary the type and number of gate lines for supplying gate signals to the subpixel SP.

Additionally, depending on the structure of the subpixel circuit SPC, there may vary the type and number of common pixel driving voltages supplied to the subpixel SP.

Since the circuit elements within each subpixel SP (in particular, the light emitting device ED implemented as an organic light emitting diode containing organic materials) are vulnerable to external moisture or oxygen, an encapsulation layer 200 may be disposed on the display panel 110 to prevent oxygen from penetrating into the circuit elements (particularly, the light emitting element device).

The encapsulation layer 200 may be configured in various forms to prevent the light emitting device ED from contacting moisture or oxygen. For example, the encapsulation layer 200 may have a structure in which an inorganic layer and an organic layer are stacked. The encapsulation layer 200 may include a first inorganic layer on the light emitting device ED, an organic layer on the first inorganic layer, and a second inorganic layer on the organic layer.

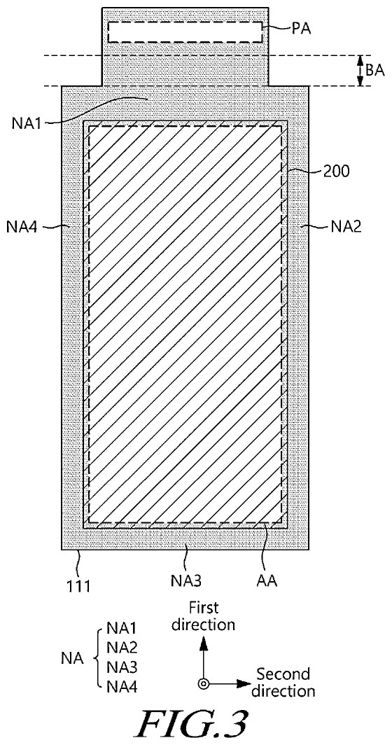

FIG. 3 illustrates a substrate 111 of a display panel 110 according to embodiments of the present disclosure.

Referring to FIG. 3, the substrate 111 of the display panel 110 according to embodiments of the present disclosure may include an active area AA capable of displaying an image and a non-active area NA in which an image is not displayed.

Referring to FIG. 3, the non-active area NA may include a first non-active area NA1 located in a first direction from the active area AA, a second non-active area NA2 located in a second direction from the active area AA, a third non-active area NA3 located in a direction opposite to the first direction from the active area AA, and a fourth non-active area NA4 located in a direction opposite to the second direction from the active area AA. For example, the first direction may be a column direction (e.g., Y-axis direction), and the second direction crossing the first direction may be a row direction (e.g., X-axis direction).

Referring to FIG. 3, the first non-active area NA1 may include a pad area PA where a plurality of pads to which at least one driving circuit or printed circuit board is electrically connected are disposed. For example, a plurality of data lines DL, a first common driving voltage line VDDL, and a second common driving voltage line VSSL may be electrically connected to the plurality of pads.

Referring to FIG. 3, the first non-active area NA1 may further include a bending area BA. In this case, the substrate 111 may be a flexible substrate. In some cases, the first non-active area NA1 may not include the bending area BA.

Referring to FIG. 3, the display panel 110 may further include a ground line disposed in the non-active area NA of the substrate 111. The ground line may be arranged from one point in the pad area PA to different points in the pad area PA via the second non-active area NA2, the third non-active area NA3 and the fourth non-active area NA4.

Referring to FIG. 3, in the display panel 110 according to embodiments of the present disclosure, the encapsulation layer 200 may have a structure in which an inorganic layer and an organic layer are stacked. In this case, an edge of the encapsulation layer 200 may be regarded as the edge of the organic layer. The encapsulation layer 200 may extend from the active area AA to a portion of the non-active area NA.

Referring to FIG. 3, the display panel 110 according to embodiments of the present disclosure may include at least one dam or at least one stopper located further outside the organic layer included in the encapsulation layer 200 in order to prevent overflow of the organic layer included in the encapsulation layer 200. At least one dam or at least one stopper may include an organic layer.

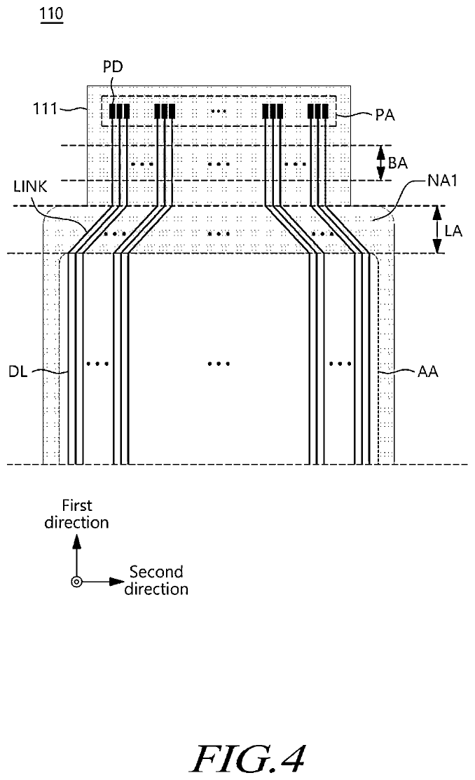

FIG. 4 illustrates a data link structure in the display panel 110 according to embodiments of the present disclosure.

Referring to FIG. 4, the display panel 110 according to embodiments of the present disclosure may include a plurality of data lines DL connected to a plurality of subpixels SP, and a plurality of pads PD disposed in the pad area PA and electrically connected to the data driving circuit 120.

Referring to FIG. 4, in the display panel 110 according to embodiments of the present disclosure, a data link structure for supplying a data voltage VDATA to a plurality of subpixels SP arranged in the active area AA may include a plurality of link lines LINK for electrically connecting a plurality of data lines DL and a plurality of pads PD.

Referring to FIG. 4, a plurality of link lines LINK may be disposed in the non-active area NA. That is, the plurality of link lines LINK may be disposed in the first non-active area NA1 including the pad area PA.

Referring to FIG. 4, the first non-active area NA1 may further include a link area LA in addition to the pad area PA and the bending area BA.

Each of the plurality of link lines LINK may be arranged across the pad area PA, the bending area BA, and the link area LA. Each of the plurality of link lines LINK may include a first end electrically connected to the pad PD disposed in the pad area PA and a second end electrically connected to the data line DL disposed in the active area AA. The line portion between both ends (i.e., first end and second end) of each of the plurality of link lines LINK may be arranged across the bending area BA and the link area LA.

Each of the plurality of link lines LINK may be made of one wire or may be made of two or more wires.

Each of the plurality of link lines LINK may be disposed on one metal layer or may be disposed on two or more metal layers.

Referring to FIG. 4, the bending area BA may be bent during the manufacturing process of the display panel 110. Accordingly, when the user looks at the display device 100 from the front of th display device 100, the bending area BA and the pad area PA may be not visible from the front.

However, when the user looks at the display device 100 from the front of the display device 100, the link area LA may be recognized as a bezel even if it is covered by the case. Therefore, in order to implement a narrow bezel, there may be required to reduce an area of the link area LA.

Referring to FIG. 4, since all of the plurality of link lines LINK in the link area LA in the first non-active area NA1 are required to be electrically connected to the plurality of data lines DL, the area of the link area LA may increase.

In particular, in the case that a length of the second direction (e.g., row direction) of the pad area PA is shorter than a length of the second direction (e.g., row direction) of the active area AA, each of the plurality of link lines LINK in the left and right areas of the link area LA is required to extend in a diagonal direction and be electrically connected to the plurality of data lines DL. Accordingly, a length of the link area LA in the first direction (e.g., column direction) may increase, and the area of the link area LA may increase.

Therefore, as shown in FIG. 4, if the display panel 110 has a data link structure in which a plurality of link lines LINK are disposed in the first non-active area NA1, the area of the link area LA within the first non-active area NA1 may increase. Accordingly, when a user looks at the display device 100 from the front, the link area LA may be recognized as a large bezel.

Therefore, there is required a data link structure capable of reducing the area of the link area LA in order to implement a narrow bezel. Accordingly, embodiments of the present disclosure propose a data link structure capable of implementing a narrow bezel.

Hereinafter, it will be described a data link structure capable of implementing a narrow bezel according to embodiments of the present disclosure.

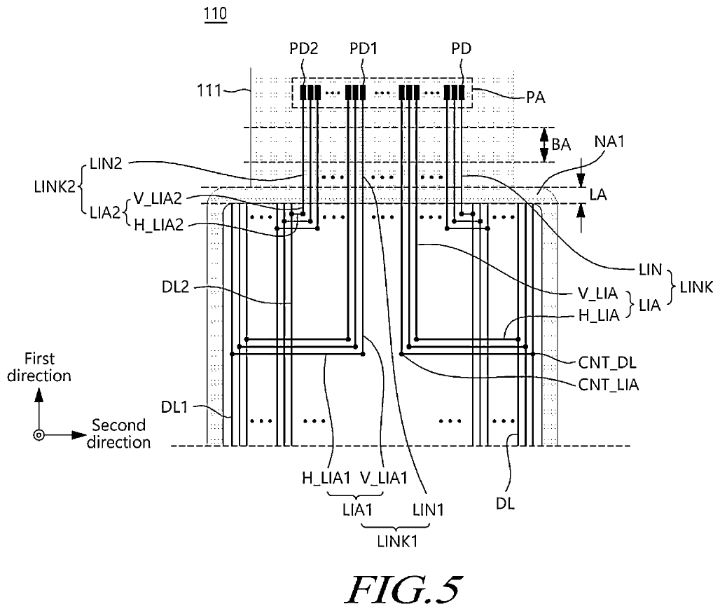

FIG. 5 illustrates a data link structure for reducing a bezel in a display panel 110 according to embodiments of the present disclosure.

Referring to FIG. 5, the non-active area NA may include a first non-active area NA1 located in a column direction from the active area AA. The first non-active area NA1 may include a pad area PA and a link area LA located in the column direction from the active area AA.

The display panel 110 according to embodiments of the present disclosure may include a data link structure capable of reducing the bezel while supplying data voltage VDATA to a plurality of subpixels SP arranged in the active area AA.

Referring to FIG. 5, the data link structure for bezel reduction according to embodiments of the present disclosure may include a plurality of link lines LINK which electrically connect a plurality of data lines DL and a plurality of pads PD.

The plurality of data lines DL may be disposed in the active area AA, and may each extend in the column direction. A plurality of data lines DL may be connected to a plurality of subpixels SP disposed in the active area AA.

A plurality of pads PD may be disposed in the pad area PA included in the first non-active area NA1.

The plurality of link lines LINK may electrically connect a plurality of pads PD disposed in the pad area PA included in the first non-active area NA1 and a plurality of data lines DL disposed in the active area AA.

Referring to FIG. 5, each of the plurality of link lines LINK included in the data link structure for the narrow bezel according to embodiments of the present disclosure may include a portion LIA disposed in the active area AA.

According to the data link structure for bezel reduction according to embodiments of the present disclosure, a plurality of link line LINK and a plurality of data lines DL may be electrically connected within the active area AA. That is, in the data link structure for bezel reduction according to embodiments of the present disclosure, the connection points CNT_DL between the plurality of link lines LINK and the plurality of data lines DL may be located in the active area AA.

Accordingly, each of the plurality of link lines LINK does not need to extend in a diagonal direction in the left and right areas of the link area LA, and the plurality of link lines LINK may shortly pass through the link area LA in the first direction (e.g., column direction), and enter the active area AA to be connected to the data line DL in the active area AA.

As shown in FIG. 5, since the display panel 110 according to embodiments of the present disclosure has a data link structure for bezel reduction, a length of the link area LA in the first direction (e.g., column direction) may be very short, or may be zero. As a result, the first non-active area NA1 recognized by the user from the front may become very small.

Referring to FIG. 5, in the data link structure for bezel reduction according to embodiments of the present disclosure, each of the plurality of link lines LINK may include an active area link line part LIA disposed in the active area AA.

Referring to FIG. 5, the active area link line part LIA may include a row-direction link line part H_LIA disposed in the active area AA and extending in the row direction, and a column-direction link line part V_LIA disposed in the active area AA and extending in the column direction.

Referring to FIG. 5, the column-direction link line part V_LIA may electrically connect the pad PD and the row-direction link line part H_LIA. The row-direction link line part H_LIA may electrically connect the column-direction link line part V_LIA and the data line DL.

Referring to FIG. 5, the row-direction link line part H_LIA and the column-direction link line part V_LIA may be electrically connected to each other at a link line connection hole CNT_LIA. The row-direction link line part H_LIA and the data line DL may be electrically connected at a data line connection hole CNT_DL.

Referring to FIG. 5, each of the plurality of link lines LINK may further include a non-active area link line part LIN disposed in the first non-active area NA1 included in the non-active area NA.

The non-active area link line part LIN may be integrated with the column-direction link line part V_LIA. Alternatively, the non-active area link line part LIN may be a wiring part which is electrically connected to the column-direction link line part V_LIA, but is disposed on a different metal layer from the column-direction link line part V_LIA. Alternatively, the non-active area link line part LIN may include a wiring part which is integral with the column-direction link line part V_LIA and a wiring part disposed in a different metal layer from the column-direction link line part V_LIA.

Meanwhile, in the case that the display panel 110 according to embodiments of the present disclosure has a data link structure for bezel reduction as shown in FIG. 5, the row-direction link line part H_LIA included in each of the plurality of link lines LINK may be disposed in the active area AA and parallel to the plurality of gate lines GL extending in the row direction.

In addition, if the display panel 110 according to embodiments of the present disclosure has a data link structure for bezel reduction as shown in FIG. 5, the row-direction link line part H_LIA included in each of the plurality of link lines LINK may vertically overlap at least one gate line GL.

Accordingly, the row-direction link line part H_LIA included in each of the plurality of link lines LINK may form a parasitic capacitance with at least one gate line GL. That is, the row-direction link line part H_LIA included in each of the plurality of link lines LINK may be capacitively connected to at least one gate line GL.

Therefore, a change in the electrical state of at least one gate line GL may also affect an electrical state of the data line DL connected to the row-direction link line part H_LIA overlapping the at least one gate line GL. That is, in the case that the display panel 110 according to embodiments of the present disclosure has a data link structure for bezel reduction as shown in FIG. 5, there may occur a crosstalk between the gate line GL and the row-direction link line part H_LIA.

That is, a voltage level change of the gate signal (e.g., the scan signal SC in FIG. 2) applied to the at least one gate line GL may generate noise in the data signal VDATA transmitted to the data line DL through the row-direction link line part H_LIA overlapping with at least one gate line GL. Here, noise generated in the data signal VDATA may have the form of an unnecessary peak voltage.

Since the display panel 110 according to embodiments of the present disclosure has a data link structure for bezel reduction as shown in FIG. 5, there may significantly reduce a bezel due to almost no link area LA visible from the front, but there may occur a crosstalk between the gate line GL and the row-direction link line part H_LIA.

Referring to FIG. 5, the plurality of data lines DL may include a first data line DL1 and a second data line DL2. The first data line DL1 may be disposed further outside the second data line DL2. The plurality of pads PD may include a first pad PD1 electrically connected to the first data line DL1 and a second pad PD2 electrically connected to the second data line DL2. A plurality of link lines LINK may include a first link line LINKI electrically connecting the first data line DL1 and the first pad PD1, and a second link line LINK2 electrically connecting the second data line DL2 and the second pad PD2.

Referring to FIG. 5, the first link line LINKI may include a first active area link line part LIA1 which is a portion disposed in the active area AA and a non-active area link line part LIN1.

The first active area link line part LIAl may include a first row-direction link line part H_LIA1 disposed in the active area AA and extending in the row direction, and a first column-direction link line part V_LIA1 disposed in the active area AA and extending in the column direction.

The first row-direction link line part H_LIA1 may electrically connect the first data line DL1 and the first column-direction link line part V_LIA1. The first column-direction link line part V_LIA1 may electrically connect the first row-direction link line part H_LIA1 and the first pad PD1.

Referring to FIG. 5, the second link line LINK2 may include a second active area link line part LIA2, which is a part disposed in the active area AA, and a non-active area link line part LIN2.

The second active area link line part LIA2 may include a second row-direction link line part H_LIA2 disposed in the active area AA and extending in the row direction, and a second column-direction link line part V_LIA2 disposed in the active area AA and extending in the column direction.

The second row-direction link line part H_LIA2 may electrically connect the second data line DL2 and the second column-direction link line part V_LIA2. The second column-direction link line part V_LIA2 may electrically connect the second row-direction link line part H_LIA2 and the second pad PD2.

In addition, the first row-direction link line part H_LIA1 included in the first link line LINK1 may vertically overlap with at least one gate line GL. Accordingly, the first row-direction link line part H_LIA1 included in the first link line LINK1 may form a parasitic capacitance with at least one gate line GL. That is, the first row-direction link line part H_LIA1 included in the first link line LINK1 may be capacitively connected to at least one gate line GL.

The second row-direction link line part H_LIA2 included in the second link line LINK2 may vertically overlap with at least one gate line GL. Accordingly, the second row-direction link line part H_LIA2 included in the second link line LINK2 may form a parasitic capacitance with at least one gate line GL. That is, the second row-direction link line part H_LIA2 included in the second link line LINK2 may be capacitively connected to at least one gate line GL.

Referring to FIG. 5, a length of the column-direction link line part V_LIA electrically connected to a data line DL located further inside among the plurality of column-direction link line parts V_LIA may be shorter. A length of the column-direction link line part V_LIA electrically connected to a data line DL located further outside among the plurality of column-direction link line parts V_LIA may be longer.

Referring to FIG. 5, a length of the row-direction link line part H_LIA electrically connected to a data line DL located further inside among the plurality of row-direction link line parts H_LIA may be shorter. A length of the row-direction link line part H_LIA electrically connected to a data line DL located further outside among the plurality of row-direction link line parts H_LIA may be longer.

Referring to FIG. 5, among the plurality of row-direction link line parts H_LIA, a length of the row-direction link line part H_LIA adjacent to the pad area PA may be shorter. Among the plurality of row-direction link line parts H_LIA, the row-direction link line part H_LIA located farther from the pad area PA may have a longer length.

Referring to FIG. 5, among the first column-direction link line part V_LIA1 and the second column-direction link line part V_LIA2, a length of the first column-direction link line part V_LIA1 electrically connected to the first data line DL1 located on the outer side among first data line DL1 and the second data line DL2 may be greater than a length of the second column-direction link line part V_LIA2.

Referring to FIG. 5, among the first row-direction link line part H_LIA1 and the second row-direction link line part H_LIA2, the first row-direction link line part H_LIA1 electrically connected to the first data line DL1 located further outside among the first data line DL1 and the second data line DL2 may have a length greater than a length of the second row-direction link line part H_LIA2.

Referring to FIG. 5, since the length of the first row-direction link line part H_LIA1 is greater than the length of the second row-direction link line part H_LIA2, a first area where the first row-direction link line part H_LIA1 overlaps at least one gate line GL may be greater than a second area where the second row-direction link line part H_LIA2 overlaps at least one gate line GL.

As a result, the parasitic capacitance formed in the first row-direction link line part H_LIA1 located far from the pad area PA may be larger than the parasitic capacitance formed in the second row-direction link line part H_LIA2 located close to the pad area PA. That is, the parasitic capacitance formed in the crosstalk between the first row-direction link line part H_LIA1 and the gate line GL may be greater than the crosstalk between the second row-direction link line part H_LIA2 and the gate line GL. This phenomenon may be referred to as “a horizontal crosstalk deviation”.

Accordingly, the noise (i.e., crosstalk noise) generated in the first data line DL1 connected to the first row-direction link line part H_LIA1 far from the pad area PA may be greater than the noise (i.e., crosstalk noise) generated in the second data line DL2 connected to the second row-direction link line part H_LIA2 located nearby. There may occur the image defects due to the horizontal crosstalk deviation.

Hereinafter, it will be described a data link structure for a narrow bezel capable of reducing horizontal crosstalk deviation while reducing the bezel.

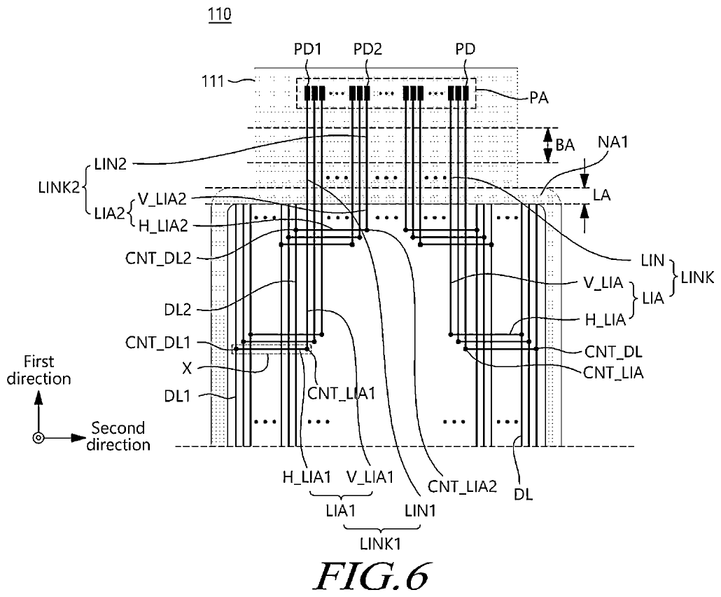

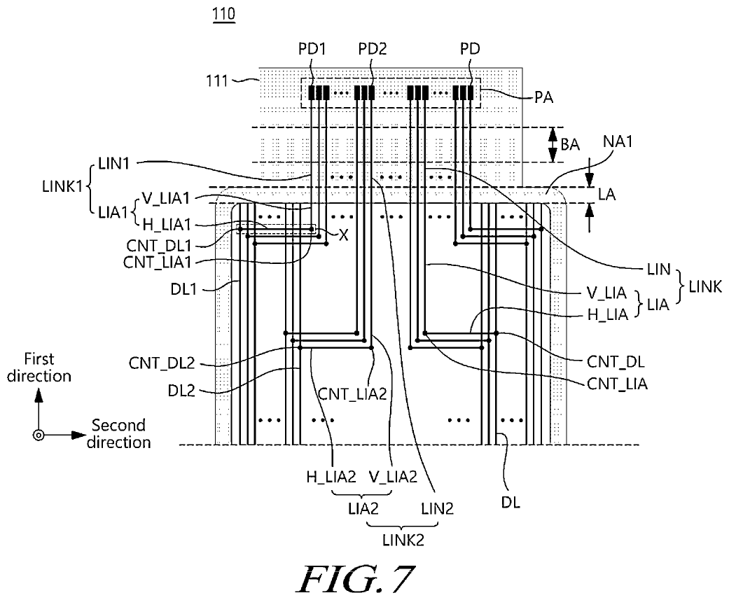

FIGS. 6 and 7 illustrate a data link structure for reducing bezels and reducing horizontal crosstalk deviation in a display panel 110 according to embodiments of the present disclosure.

Referring to FIGS. 6 and 7, the display panel 110 according to embodiments of the present disclosure may include a substrate 111 including an active area AA on which a plurality of subpixels SP are arranged and a non-active area NA including a pad area PA located in a column direction from the active area AA, a plurality of gate lines GL arranged in the active area AA and each extending in a row direction, a plurality of data lines DL arranged in the active area AA and each extending in the column direction, and a plurality of pads PD arranged in the pad area PA.

Referring to FIGS. 6 and 7, the data link structure included in the display panel 110 according to embodiments of the present disclosure may include a plurality of link lines LINK which electrically connect a plurality of pads PD and a plurality of data lines DL.

Referring to FIGS. 6 and 7, each of the plurality of link line LINK may include an active area link line part LIA disposed in the active area AA. The active area link line part LIA may include a row-direction link line part H_LIA disposed in the active area AA and extending in the row direction, and a column-direction link line part V_LIA disposed in the active area AA and extending in the column direction.

Referring to FIGS. 6 and 7, each of the plurality of link line LINK may include a non-active area link line part LIN disposed in the non-active area NA.

The non-active area link line part LIN may be integrated with the column-direction link line part V_LIA of the active area link line part LIA. Alternatively, the non-active area link line part LIN may be a wiring part which is electrically connected to the column-direction link line part V_LIA, but is disposed on a different metal layer from the column-direction link line part V_LIA. Alternatively, the non-active area link line part LIN may include a wiring part which is integral with the column-direction link line part V_LIA, and a wiring part disposed in a different metal layer from the column-direction link line part V_LIA.

Referring to FIGS. 6 and 7, at least a portion of the row-direction link line part H_LIA included in each of the plurality of link lines LINK may intersect at least one data line DL, and may overlap with at least one gate line GL in the vertical direction. Accordingly, the row-direction link line part H_LIA included in each of the plurality of link lines LINK may be disposed on a different metal layer from the plurality of data lines DL.

Referring to FIGS. 6 and 7, all or part of the row-direction link line part H_LIA included in each of the plurality of link lines LINK may be arranged parallel to the plurality of gate lines GL.

Referring to FIGS. 6 and 7, in the data link structure included in the display panel 110 according to embodiments of the present disclosure, at least a part of the row-direction link line part H_LIA included in each of the plurality of link lines LINK may overlap in the vertical direction with at least one gate line GL.

Referring to FIGS. 6 and 7, in the data link structure included in the display panel 110 according to embodiments of the present disclosure, the row-direction link line parts H_LIA included in each of the plurality of link lines LINKs may have lengths corresponding to each other. Here, the fact that the lengths of the plurality of row-direction link line parts H_LIA correspond to each other may mean that the lengths of the plurality of row-direction link line parts H_LIA are substantially the same even if the lengths are the same or slightly different.

As described above, the plurality of row-direction link line parts H_LIA have lengths corresponding to each other, so that the bezel can be reduced and horizontal crosstalk deviation can also be reduced.

Referring to FIGS. 6 and 7, the plurality of data lines DL may include a first data line DL1 and a second data line DL2, and the plurality of pads PD may include a first pad PD1 and a second pad PD2.

Referring to FIGS. 6 and 7, the plurality of link lines LINK may include a first link line LINK1 and a second link line LINK2.

The first link line LINK1 may electrically connect the first data line DL1, which is located on the outer side among the first data line DL1 and the second data line DL2, to the first pad PD1 located on the outer side among the first pad PD1 and the second pad PD2.

The second link line LINK2 may electrically connect the second data line DL2 located inside among the first data line DL1 and the second data line DL2 to the second pad PD2 located further inside among the first pad PD1 and the second pad PD2.

Referring to FIGS. 6 and 7, the first link line LINKI may include a first active area link line part LIA1, which is a part disposed in the active area AA. In addition, a second link line LINK2 may include a second active area link line part LIA2, which is a portion disposed in the active area AA.

Referring to FIGS. 6 and 7, the bezel may be reduced due that each of the first link LINK1 and the second link line LINK2 include a wire part disposed in the active area AA.

Referring to FIGS. 6 and 7, in the case that the first data line DL1 and the first pad PDI are electrically connected, and the second data line DL2 and the second pad PD2 are electrically connected, the first data line DL1 among the first data line DL1 and the second data line DL2 may be disposed on the outside, and the first pad PD1 among the first pad PD1 and the second pad PD2 may be disposed on the outside. Therefore, the first active area link line part LIA1 and the second active area link line part LIA2 may have the same length. Accordingly, there may also be reduced a horizontal crosstalk deviation.

Referring to FIGS. 6 and 7, the row-direction link line part H_LIA included in each of the plurality of link lines LINK may vertically overlap at least one gate line GL among the plurality of gate lines GL.

Referring to FIGS. 6 and 7, the overlapping area of the row-direction link line part H_LIA included in each of the plurality of link lines LINK and at least one gate line GL may be the same.

Referring to FIGS. 6 and 7, the first link line LINK1 may include a first row-direction link line part H_LIA1 and a first column-direction link line part V_LIA1.

The first row-direction link line part H_LIA1 may electrically connect the first data line DL1 and the first column-direction link line part V_LIA1, and the first column-direction link line part V_LIA1 may electrically connect the first row-direction link line part H_LIA1 and the first pad PD1.

Referring to FIGS. 6 and 7, the second link line LINK2 may include a second row-direction link line part H_LIA2 and a second column-direction link line part V_LIA2.

The second row-direction link line part H_LIA2 may electrically connect the second data line DL2 and the second column-direction link line part V_LIA2, and the second column-direction link line part V_LIA2 may electrically connect the second row-direction link line part H_LIA2 and the second pad PD2.

Referring to FIGS. 6 and 7, in the data link structure according to embodiments of the present disclosure, the first data line DL1 may be located further outside the second data line DL2, and the first pad PD1 may be located further outside the second pad PD2.

Referring to FIGS. 6 and 7, in the data link structure according to embodiments of the present disclosure, the first row-direction link line part H_LIA1 and the second row-direction link line part H_LIA2 may have the same length.

Referring to FIGS. 6 and 7, in the data link structure according to embodiments of the present disclosure, a first area overlapping the first row-direction link line part H_LIA1 and the at least one first gate line GL may be same as a second area where the second row-direction link line part H_LIA2 and at least one second gate line GL overlap with each other.

A vertical separation distance between the first row-direction link line part H_LIA1 and the at least one first gate line GL may be the same as a vertical separation distance between the second row-direction link line part H_LIA2 and at least one second gate line GL.

Accordingly, the parasitic capacitance between the first row-direction link line part H_LIA1 and the at least one first gate line GL may correspond to a parasitic capacitance between the second row-direction link line part H_LIA2 and at least one second gate line GL.

In addition, a crosstalk between the first row-direction link line part H_LIA1 and at least one first gate line GL may be the same as a crosstalk between the second row-direction link line part H_LIA2 and at least one second gate line GL.

According to the data link structure according to the above-described embodiments of the present disclosure, it may be possible to reduce the bezel and reduce the horizontal crosstalk deviation.

Referring to FIGS. 6 and 7, the data link structure according to embodiments of the present disclosure may include a first data line connection hole CNT_DL1 where the first data line DL1 and the first row-direction link line part H_LIA1 are connected, a first link line connection hole CNT_LIA1 where the first row-direction link line part H_LIA 1 and the first column-direction link line part V_LIA1 are connected, a second data line connection hole CNT_DL2 where the second data line DL2 and the second row-direction link line part H_LIA2 are connected, and a second link line connection hole CNT_LIA2 where the second row-direction link line part H_LIA2 and the second column-direction link line part V_LIA2 are connected.

Referring to FIGS. 6 and 7, an imaginary line connecting the first data line connection hole CNT_DL1, the first link line connection hole CNT_LIA1, the second link line connection hole CNT_LIA2 and the second data line connection hole CNT_DL2 may include the corners of a parallelogram or trapezoid.

Referring to FIGS. 6 and 7, the first data line connection hole CNT_DL1 may be located further outside the second data line connection hole CNT_DL2, and the first link line connection hole CNT_LIA1 may be located further outside the second link line connection hole CNT_LIA2.

Referring to FIG. 6, the distance between the first row-direction link line part H_LIA1 and the pad area PA may be greater than the distance between the second row-direction link line part H_LIA2 and the pad area PA.

Referring to FIG. 6, the distance between the first data line connection hole CNT_DL1 and the pad area PA may be greater than the distance between the second data line connection hole CNT_DL2 and the pad area PA.

Referring to FIG. 6, the length of the first row-direction link line part H_LIA1 may correspond to the length of the second row-direction link line part H_LIA2, and a length of the first column-direction link line part V_LIA1 may be greater than a length of the second column-direction link line part V_LIA2.

Referring to FIG. 6, the first column-direction link line part V_LIA1 may overlap the second row-direction link line part H_LIA2 in the vertical direction.

Referring to FIG. 7, the distance between the second row-direction link line part H_LIA2 and the pad area PA may be greater than the distance between the first row-direction link line part H_LIA1 and the pad area PA.

Referring to FIG. 7, the distance between the second data line connection hole CNT_DL2 and the pad area PA may be greater than the distance between the first data line connection hole CNT_DL1 and the pad area PA.

Referring to FIG. 7, the length of the second row-direction link line part H_LIA2 may correspond to the length of the first row-direction link line part H_LIA1, and the length of the second column-direction link line part V_LIA2 may be greater that the length of the first column-direction link line part V_LIA1.

Referring to FIG. 7, the first column-direction link line part V_LIA1 may not overlap the second row-direction link line part H_LIA2 in the vertical direction.

According to the data link structure according to the embodiments of the present disclosure described with reference to FIGS. 6 and 7, there may be possible both bezel reduction and horizontal crosstalk deviation reduction.

Referring to FIGS. 6 and 7, the plurality of gate lines GL may include a first gate line GL1 which at least partially overlaps the first row-direction link line part H_LIA1, and a second gate line GL2 which at least partially overlaps the second row-direction link line part H_LIA2.

At the timing of the voltage level change of the gate signal applied to the first gate line GL1, the first data signal VDATA applied to the first data line DL1 may temporarily have a voltage added or subtracted by a first peak voltage.

At the timing of the voltage level change of the gate signal applied to the second gate line GL2, the second data signal VDATA applied to the second data line DL2 may temporarily have a voltage added or subtracted by a second peak voltage.

According to the data link structure according to the embodiments of the present disclosure, the horizontal crosstalk deviation may be reduced, so that the first peak voltage and the second peak voltage may have voltage values corresponding to each other.

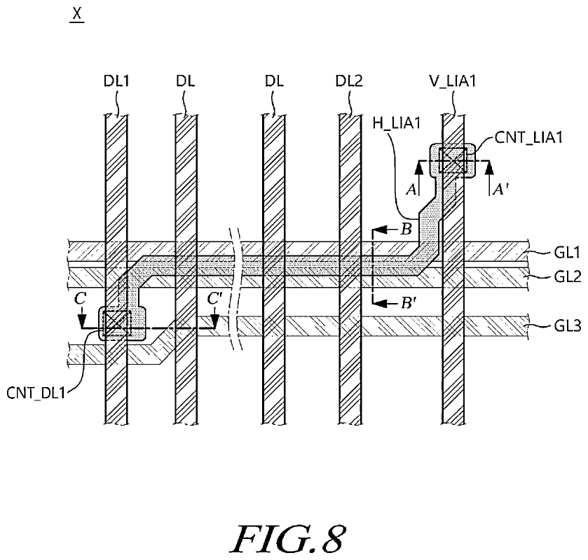

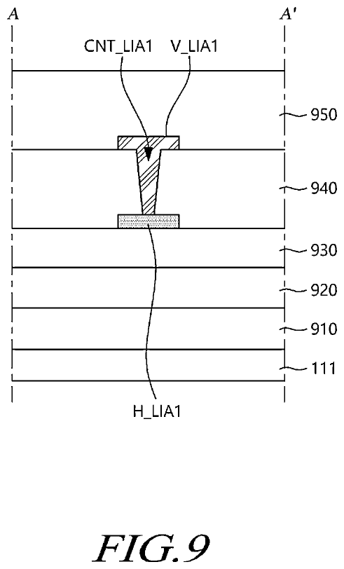

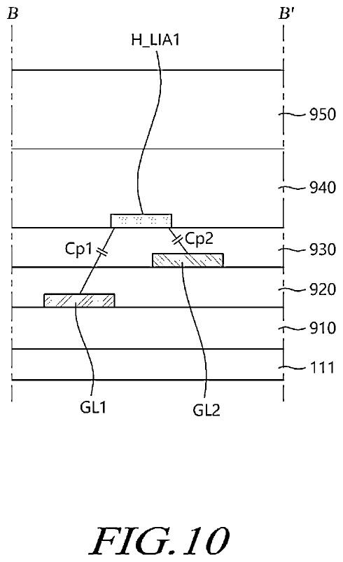

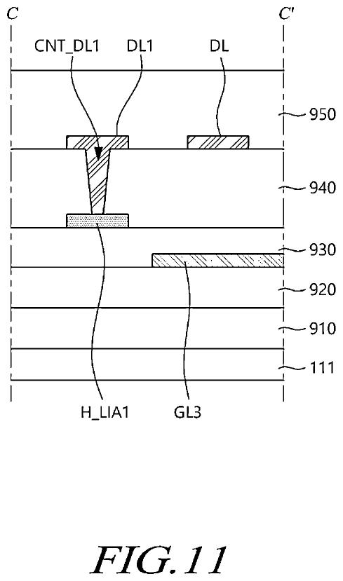

FIG. 8 is a plan view of a partial area of the display panel of FIG. 6 or FIG. 7 according to one embodiment, FIG. 9 is a cross-sectional view taken along line A-A′ of FIG. 8 according to one embodiment, FIG. 10 is a cross-sectional view taken along line B-B′ of FIG. 8 according to one embodiment, and FIG. 11 is a cross-sectional view taken along line C-C′ of FIG. 8 according to one embodiment.

Referring to FIG. 8, in a partial area X of the display panel 110, there may be disposed a first data line DL1, a second data line DL2, and a plurality of data lines DL between the first data line DL1 and the second data line DL2.

Referring to FIG. 8, the first gate line GL1, the second gate line GL2, and the third gate line GL3 may be disposed in a partial area X of the display panel 110.

Referring to FIG. 8, a first column-direction link line part V_LIA1 and a first row-direction link line part H_LIA1 may be disposed in a partial area X of the display panel 110.

Referring to FIG. 8, the first column-direction link line part V_LIA1 and the first row-direction link line part H_LIA1 may be electrically connected, and the first row-direction link line part H_LIA1 may be electrically connected to the first data line DL1.

Referring to FIG. 8, the first row-direction link line part H_LIA1 may intersect the second data line DL2. The first row-direction link line part H_LIA1 may overlap the second data line DL2 in the vertical direction. The first row-direction link line part H_LIA1 may vertically overlap at least a portion of the at least one gate line GL.

Referring to FIGS. 8 and 9, the first column-direction link line part V_LIA1 may be electrically connected to the first row-direction link line part H_LIA1 through the first link line connection hole CNT_LIA1.

Referring to FIGS. 8 and 10, the first row-direction link line part H_LIA1 may vertically overlap at least a portion of the first gate line GL1 and at least a portion of the second gate line GL2.

Referring to FIGS. 8 and 10, a first parasitic capacitor Cp1 may be formed between the first row-direction link line part H_LIA1 and the first gate line GL1, and a second parasitic capacitor Cp2 may be formed between the first row-direction link line part H_LIA1 and the second gate line GL2.

Therefore, at the timing when the voltage level of the gate signal applied to at least one of the first gate line GL1 and the second gate line GL2 changes, there may occur a peak noise in the first row-direction link line part H_LIA1.

Referring to FIGS. 8 and 11, the first row-direction link line part H_LIA1 may be electrically connected to the first data line DL1 through the first data line connection hole CNT_DL1.

Referring to FIGS. 9 to 11, in the active area AA, the first column-direction link line part V_LIA1 may include the same material as the first data line DL1, and the first row-direction link line part H_LIA1 may include a material different from that of the first data line DL1.

Referring to FIGS. 9 to 11, the display panel 110 may include a first insulating film 910 on the substrate 111, a first gate line GL1 on the first insulating film 910, a second insulating film 920 on the first gate line GL1, a second gate line GL2 on the second insulating film 920, a third insulating film 930 on the second gate line GL2, a first planarization layer 940 on the third insulating film 930, and a second planarization layer 950 on first planarization layer 940.

Referring to FIGS. 9 to 11, the first to third insulating films 910, 920 and 930 may be composed of an inorganic film or an organic film. The first planarization layer 940 and the second planarization layer 950 may be a type of insulating film that performs a planarization function, and may be composed of an organic film.

Referring to FIGS. 9 to 11, the display panel 110 may further include a third gate line GL3 disposed between the second insulating film 920 and the third insulating film 930.

Referring to FIGS. 9 to 11, the first row-direction link line part H_LIA1 may be disposed between the third insulating film 930 and the first planarization layer 940, and the first column-direction link line V_LIA1 may be disposed between the first planarization layer 940 and the second planarization layer 950.

Referring to FIG. 10, at least a portion of the first row-direction link line part H_LIA1 may vertically overlap with at least a portion of at least one of the first gate line GL and the second gate line GL.

Referring to FIG. 11, the data lines DL1 and DL may be disposed in the same metal layer as the first column-direction link line part V_LIA1.

Referring to FIGS. 8 and 9, the first column-direction link line part V_LIA1 may be electrically connected to the first row-direction link line part H_LIA1 through the first link line connection hole CNT_LIA1 of the first planarization layer 940.

Referring to FIGS. 8 and 11, the first row-direction link line part H_LIA1 may be electrically connected to the first data line DL1 through the first data line connection hole CNT_DL1 of the first planarization layer 940.

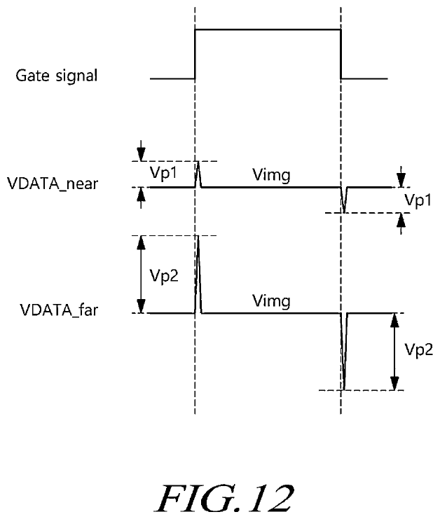

FIG. 12 illustrates a data signal transmitted to a data line DL according to a data link structure for bezel reduction according to embodiments of the present disclosure.

FIG. 12 illustrates data signals VDATA_near and VDATA_far according to changes in the voltage level of the gate signal in the display panel 110 having the data link structure of FIG. 5.

Referring to FIG. 12, when the voltage level of the gate signal changes from low level to high level, a data signal VDATA_near in the row-direction link line part H_LIA located relatively close to the pad area PA may be a voltage Vimg+Vp1 obtained by adding a first peak voltage Vp1 to the original data voltage Vimg.

When the voltage level of the gate signal changes from high level to low level, the data signal VDATA_near in the row-direction link line part H_LIA located relatively close to the pad area PA may be a voltage Vimg−Vp1 obtained by subtracting the first peak voltage Vp1 from the original data voltage Vimg.

Referring to FIG. 12, when the voltage level of the gate signal changes from low level to high level, the data signal VDATA_far in the row-direction link line part H_LIA located relatively far from the pad area PA may be a voltage Vimg+Vp2 obtained by adding a second peak voltage Vp2 to the original data voltage Vimg.

When the voltage level of the gate signal changes from high level to low level, the data signal VDATA_far in the row-direction link line part H_LIA located relatively far from the pad area PA may be a voltage Vimg−Vp2 obtained by subtracting the second peak voltage Vp2 from the original data voltage Vimg.

According to the data link structure of FIG. 5, the row-direction link line part H_LIA located relatively far from the pad area PA may be longer that the row-direction link line part H_LIA located relatively close to the pad area PA. Accordingly, the parasitic capacitance formed between the row-direction link line part H_LIA located relatively far from the pad area PA and the gate line GL may be greater the parasitic capacitance formed between the row-direction link line part H_LIA located relatively close to the pad area PA and gate line GL.

Accordingly, the influence (i.e., crosstalk) received from the gate line GL on the row-direction link line part H_LIA located relatively far from the pad area PA may be greater than the influence (i.e., crosstalk) of the row-direction link line part H_LIA located relatively close to the pad area PA from the gate line GL.

Therefore, the second peak voltage Vp2, which is the horizontal crosstalk noise generated from the row-direction link line part H_LIA located relatively far from the pad area PA, may be greater than the first peak voltage Vp1, which is the horizontal crosstalk noise generated from the row-direction link line part H_LIA located relatively close to the pad area PA.

As described above, in the case of having the data link structure of FIG. 5, the bezel can be reduced, but horizontal crosstalk deviation may occur.

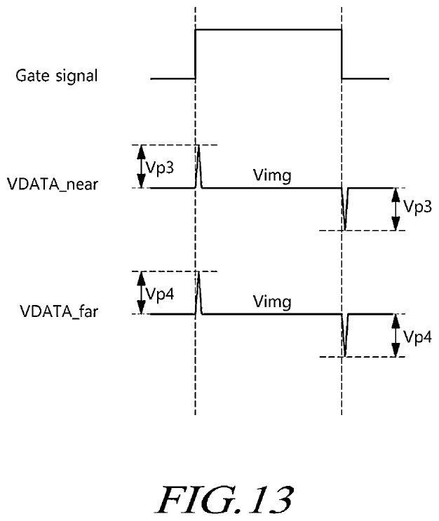

FIG. 13 illustrates a data signal transmitted to a data line DL according to a data link structure for reducing the bezel and horizontal crosstalk deviation according to embodiments of the present disclosure.

FIG. 13 illustrates data signals VDATA_near and VDATA_far according to changes in the voltage level of a gate signal in the display panel 110 having the data link structure of FIG. 6 or 7.

Referring to FIG. 13, when the voltage level of the gate signal changes from low level to high level, a data signal VDATA_near in the row-direction link line part H_LIA located relatively close to the pad area PA may be a voltage Vimg+Vp3 obtained by adding a third peak voltage Vp3 to the original data voltage Vimg.

When the voltage level of the gate signal changes from high level to low level, the data signal VDATA_near in the row-direction link line part H_LIA located relatively close to the pad area PA may be a voltage Vimg−Vp3 obtained by subtracting the third peak voltage Vp3 from the original data voltage Vimg.

Referring to FIG. 13, when the voltage level of the gate signal changes from low level to high level, the data signal VDATA_far in the row-direction link line part H_LIA located relatively far from the pad area PA may be a voltage Vimg+Vp4 obtained by adding a fourth peak voltage Vp4 to the original data voltage Vimg.

When the voltage level of the gate signal changes from high level to low level, the data signal VDATA_far in the row-direction link line part H_LIA located relatively far from the pad area PA may be a voltage Vimg−Vp4 obtained by subtracting the fourth peak voltage Vp4 from the original data voltage Vimg.

Comparing FIGS. 13 and 12, the third peak voltage Vp3 and the fourth peak voltage Vp4 may have the same or substantially the same peak voltage magnitude (i.e., peak voltage value). In addition, the third peak voltage Vp3 and the fourth peak voltage Vp4 may have a peak voltage magnitude (i.e., peak voltage value) larger than the first peak voltage Vp1, and may have a peak voltage magnitude (i.e., peak voltage value) smaller than the second peak voltage Vp2. (i.e., Vp1<Vp3=Vp4<Vp2).

That is, according to the data link structure of FIGS. 6 and 7, a length of the row-direction link line part H_LIA located relatively far from the pad area PA may be the same or substantially the same as the length of the row-direction link line part H_LIA located relatively close to the pad area PA.

Accordingly, the parasitic capacitance formed between the row-direction link line part H_LIA located relatively far from the pad area PA and the gate line GL may be the same or substantially the same as the parasitic capacitance formed between the row-direction link line part H_LIA located relatively close to the pad area PA and the gate line GL.

Accordingly, the influence (i.e., crosstalk) received from the gate line GL on the row-direction link line part H_LIA located relatively far from the pad area may be the same or substantially the same as the influence (i.e., crosstalk) of the row-direction link line part H_LIA located relatively close to the pad area PA from the gate line GL.

Therefore, in the data link structure of FIG. 6 or 7, the fourth peak voltage Vp4, which is the horizontal crosstalk noise generated from the row-direction link line part H_LIA located relatively far from the pad area PA may be the same or substantially the same as the third peak voltage Vp3, which is the horizontal crosstalk noise generated from the row-direction link line part H_LIA located relatively close to the pad area PA.

In addition, in the data link structure of FIG. 6 or 7, the fourth peak voltage Vp4, which is the horizontal crosstalk noise generated from the row-direction link line part H_LIA located relatively far from the pad area PA, and the third peak voltage Vp3, which is the horizontal crosstalk noise generated from the row-direction link line part H_LIA located relatively close to the pad area PA may be greater than the first peak voltage Vp1, which is the horizontal crosstalk noise generated from the row-direction link line part H_LIA located relatively close to the pad area PA in the data link structure of FIG. 5.

However, the fourth peak voltage Vp4, which is the horizontal crosstalk noise generated from the row-direction link line part H_LIA located relatively far from the pad area PA, and the third peak voltage Vp3, which is the horizontal crosstalk noise generated from the row-direction link line part H_LIA located relatively close to the pad area PA may become smaller than the second peak voltage Vp2, which is the horizontal crosstalk noise generated from the row-direction link line part H_LIA located relatively far from the pad area PA.

Therefore, in the data link structure of FIG. 6 or 7, the average value of the horizontal crosstalk noise generated from the plurality of row-direction link line part H_LIA disposed on the display panel 110 may be greater than the minimum value of horizontal crosstalk noise (e.g., first peak voltage Vp1) generated from the plurality of row-direction link line part H_LIA disposed on the display panel 110 according to the data link structure of FIG. 5., however may be smaller than the maximum value of horizontal crosstalk noise (e.g., second peak voltage Vp2) generated from the plurality of row-direction link line part H_LIA disposed on the display panel 110 according to the data link structure of FIG. 5.

Accordingly, in the case of having the data link structure of FIG. 6 or FIG. 7, it is possible to reduce the horizontal crosstalk deviation in addition to the bezel.

It will be briefly described embodiments of the present disclosure as follows.

The display device according to embodiments of the present disclosure may include a substrate including an active area on which a plurality of subpixels are arranged and a non-active area including a pad area located in a column direction from the active area, a plurality of gate lines disposed in the active area and each extending in a row direction, a plurality of data lines disposed in the active area and each extending in the column direction, a plurality of pads disposed in the pad area, and a plurality of link lines electrically connecting the plurality of pads and the plurality of data lines.

Each of the plurality of link lines may include a row-direction link line part extending in the row direction and a column-direction link line part extending in the column direction.

The row-direction link line part included in each of the plurality of link lines may be disposed in the active area, and at least a portion of the column-direction link line part included in each of the plurality of link line may be disposed in the active area.

The row-direction link line part included in each of the plurality of link lines may vertically overlap at least one gate line among the plurality of gate lines.

The parasitic capacitances between the row-direction link line parts included in each of the plurality of link lines and at least one gate line may correspond to each other. That is, parasitic capacitances formed by each of the plurality of row-direction link line parts and at least one gate line may be the same or substantially the same.

In the case that a vertical separation distance between the row-direction link line part included in each of the plurality of linklines and at least one gate line is ‘d’, and the area where the row-direction link line part included in each of the plurality of link lines and at least one gate line overlap is ‘A’, the capacitance (i.e., parasitic capacitance) formed between the row-direction link line part included in each of the plurality of link lines and at least one gate line may be proportional to (A/d).

If it is assumed that the vertical separation distance between the row-direction link line part included in each of the plurality of link lines and at least one gate line is constant, the overlapping area of the row-direction link line part included in each of the plurality of link lines and at least one gate line may correspond to each other. That is, the areas where each of the plurality of row-direction link line parts overlaps with at least one gate line may correspond to each other. This may mean that the area where each of the plurality of row-direction link line parts overlaps at least one gate line is the same or substantially the same.

The row-direction link line parts included in each of the plurality of link lines may have lengths corresponding to each other. That is, the lengths of each of the plurality of row-direction link line parts may correspond to each other. This may mean that the length of each of the plurality of row-direction link line parts may be the same or substantially the same.

The plurality of data lines may include a first data line and a second data line, and the plurality of pads may include a first pad and a second pad,

The plurality of link lines may include a first link line electrically connecting the first data line and the first pad and a second link line electrically connecting the second data line and the second pad.

The first link line includes a first row-directtion link line part and a first column-direction link line part.

The first row-direction link line part may electrically connect the first data line and the first column-direction link line part.

The first column-direction link line part may electrically connect the first row-direction link line part and the first pad.

The second link line may include a second row-directtion link line part and a second column-direction link line part.

The second row-direction link line part may electrically connect the second data line and the second column-direction link line part.

The second column-direction link line part may electrically connect the second row-direction link line part and the second pad.

The first data line may be located outside the second data line, and the first pad may be located further outside the second pad.

The first row-direction link line part and the second row-direction link line part may have the same length.

The first area where the first row-direction link line part and at least one first gate line overlap may be the same as the second area where the second row-direction link line part and at least one second gate line overlap.

The display device may further include a first data line connection hole through which the first data line and the first row-direction link line part are connected, a first link line connection hole through which the first row-direction link line part and the first column-direction link line part are connected, a second data line connection hole through which the second data line and the second row-direction link line part are connected, and a second link line connection hole through which the second row-direction link line part and the second column-direction link line part are connected.

An imaginary line connecting the first data line connection hole, the first link line connection hole, the second link line connection hole and the second data line connection hole may include corners of a parallelogram or trapezoid. Here, the trapezoid may be a trapezoid that is close to a parallelogram.

An imaginary line connecting the first data line connection hole, the first link line connection hole, the second link line connection hole, and the second data line connection hole may form a corner of a parallelogram.

The first data line connection hole may be located further outside the second data line connection hole, and the first link line connection hole may be located further outside the second link line connection hole.

An example of a data link structure, a distance between the first row-direction link line part and the pad area may be greater than a distance between the second row-direction link line part and the pad area.

In this case, the length of the first row-direction link line part may correspond to the length of the second row-direction link line part, and the length of the first column-direction link line part may be greater than the length of the second column-direction link line part.

Additionally, the first column-direction link line part may vertically overlap the second row-direction link line part.

As another example of a data link structure, a distance between the second row-direction link line part and the pad area may be greater than a distance between the first row-direction link line part and the pad area.

In this case, a length of the second row-direction link line part may corresponds to a length of the first row-direction link line part, and a length of the second column-direction link line part may be greater than a length of the first column-direction link line part.

In addition, the first column-direction link line part may not overlap the second row-direction link line part in a vertical direction.

The plurality of gate lines may include the first gate line which at least partially overlaps the first row-direction link line part and the second gate line which at least partially overlaps the second row-direction link line part.

At the timing of a voltage level change of a gate signal applied to the first gate line, a data signal applied to the first data line may temporarily have a voltage added or subtracted by a first peak voltage.

At the timing of a voltage level change of a gate signal applied to the second gate line, a data signal applied to the second data line may temporarily have a voltage added or subtracted by a second peak voltage.

The first peak voltage and the second peak voltage may have voltage values corresponding to each other.

The column-direction link line part may include the same material as the plurality of data lines, and the row-direction link line part may include a different material from the plurality of data lines.

The display device of claim 16 may further include a first insulating film on the substrate, a first gate line on the first insulating film, a second insulating film on the first gate line, a second gate line on the second insulating film, a third insulating film on the second gate line, a first planarization layer on the third insulating film, and a second planarization layer on the first planarization layer.

The row-direction link line part may be disposed between the third insulating film and the first planarization layer, and the column-direction link line part may be disposed between the first planarization layer and the second planarization layer.

At least a portion of the row-direction link line part may vertically overlap with at least a portion of at least one of the first gate line and the second gate line.

A display panel according to embodiment of the present disclosure may include a substrate including an active area on which a plurality of subpixels are arranged and a non-active area including a pad area located in a column direction from the active area, a plurality of pads disposed in the pad area, a plurality of data lines disposed in the active area and each extending in a column direction, and a plurality of link lines electrically connecting the plurality of pads and the plurality of data lines.

The plurality of data lines may include a first data line and a second data line, and the plurality of pads may include a first pad and a second pad.

The plurality of link lines may include a first link line which electrically connects the first data line located further outside among the first data line and the second data line with the first pad located on the outer side among the first pad and the second pad, and a second link line which electrically connects the second data line located further inside among the first data line and the second data line to the second pad located further inside among the first pad and the second pad.

Each of the first link line and the second link line may include a portion disposed in the active area.

According to the embodiments of the present disclosure described above, it is possible to provide a display device and a display panel having a data link structure for bezel reduction.

According to embodiments of the present disclosure, it is possible to provide a display device and a display panel having a data link structure capable of reducing crosstalk deviation between a link line and a gate line.

According to embodiments of the present disclosure, it is possible to provide a display device and a display panel having a data link structure capable of reducing the bezel and horizontal crosstalk deviation.

According to embodiments of the present disclosure, it is possible to reduce the weight of the display panel and display device by reducing the bezel using a data link structure.

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate including an active area on which a plurality of subpixels are arranged and a non-active area including a pad area located in a column direction from the active area;
a plurality of gate lines in the active area, each gate line extending in a row direction;
a plurality of data lines in the active area, each data line extending in the column direction;
a plurality of pads in the pad area; and
a plurality of link lines electrically connecting the plurality of pads and the plurality of data lines, each of the plurality of link lines including a row-direction link line part extending in the row direction and a column-direction link line part extending in the column direction,
wherein the row-direction link line part included in each of the plurality of link lines is in the active area, and at least a portion of the column-direction link line part included in each of the plurality of link lines is in the active area,
wherein the row-direction link line part included in each of the plurality of link lines vertically overlaps at least one gate line among the plurality of gate lines,
wherein overlapping areas between row-direction link line parts included the plurality of link lines and the at least one gate line correspond to each other.

2. The display device of claim 1, wherein row-direction link line parts included in the plurality of link lines have lengths corresponding to each other.

3. The display device of claim 1, wherein the plurality of data lines include a first data line and a second data line, and the plurality of pads include a first pad and a second pad,
wherein the plurality of link lines include a first link line electrically connecting the first data line and the first pad and a second link line electrically connecting the second data line and the second pad,
wherein the first link line includes a first row-direction link line part and a first column-direction link line part, and the first row-direction link line part electrically connects the first data line and the first column-direction link line part, and the first column-direction link line part electrically connects the first row-direction link line part and the first pad,
wherein the second link line includes a second row-direction link line part and a second column-direction link line part, and the second row-direction link line part electrically connects the second data line and the second column-direction link line part, and the second column-direction link line part electrically connects the second row-direction link line part and the second pad,
wherein a first area overlapping the first row-direction link line part and at least one first gate line is equal to a second area overlapping the second row-direction link line part and at least one second gate line.

4. The display device of claim 3, wherein the first data line is located outside the second data line, and the first pad is located further outside the second pad.

5. The display device of claim 3, wherein the first row-direction link line part and the second row-direction link line part have a same length.

6. The display device of claim 3, further comprising:
a first data line connection hole through which the first data line and the first row-direction link line part are connected;
a first link line connection hole through which the first row-direction link line part and the first column-direction link line part are connected;
a second data line connection hole through which the second data line and the second row-direction link line part are connected; and
a second link line connection hole through which the second row-direction link line part and the second column-direction link line part are connected.

7. The display device of claim 6, wherein an imaginary line connecting the first data line connection hole, the first link line connection hole, the second link line connection hole and the second data line connection hole includes corners of a parallelogram or trapezoid.

8. The display device of claim 6, wherein the first data line connection hole is located further outside the second data line connection hole, and the first link line connection hole is located further outside the second link line connection hole.

9. The display device of claim 3, wherein a distance between the first row-direction link line part and the pad area is greater than a distance between the second row-direction link line part and the pad area.

10. The display device of claim 5, wherein a length of the first column-direction link line part is greater than a length of the second column-direction link line part.

11. The display device of claim 3, wherein the first column-direction link line part vertically overlaps the second row-direction link line part.

12. The display device of claim 3, wherein a distance between the second row-direction link line part and the pad area is greater than a distance between the first row-direction link line part and the pad area.

13. The display device of claim 5, wherein a length of the second column-direction link line part is greater than a length of the first column-direction link line part.

14. The display device of claim 3, wherein the first column-direction link line part does not overlap the second row-direction link line part in a vertical direction.

15. The display device of claim 3, wherein the plurality of gate lines include the at least one first gate line that at least partially overlaps the first row-direction link line part and the at least one second gate line that at least partially overlaps the second row-direction link line part,
wherein, at a timing of a voltage level change of a gate signal applied to the at least one first gate line, a data signal applied to the first data line temporarily has a voltage added or subtracted by a first peak voltage,
wherein, at a timing of a voltage level change of a gate signal applied to the at least one second gate line, a data signal applied to the second data line temporarily has a voltage added or subtracted by a second peak voltage,
wherein the first peak voltage and the second peak voltage have voltage values corresponding to each other.

16. The display device of claim 1, wherein the column-direction link line part includes a same material as the plurality of data lines, and the row-direction link line part includes a different material from the plurality of data lines.

17. The display device of claim 16, further comprising:
a first insulating film on the substrate;
a first gate line on the first insulating film;
a second insulating film on the first gate line;
a second gate line on the second insulating film;
a third insulating film on the second gate line;
a first planarization layer on the third insulating film; and
a second planarization layer on the first planarization layer,
wherein the row-direction link line part is between the third insulating film and the first planarization layer, and the column-direction link line part is between the first planarization layer and the second planarization layer,
wherein at least a portion of the row-direction link line part vertically overlaps with at least a portion of at least one of the first gate line and the second gate line.

18. A display panel comprising:
a substrate including an active area on which a plurality of subpixels are arranged and a non-active area including a pad area located in a column direction from the active area;
a plurality of data lines in the active area, each data line extending in the column direction;
a plurality of pads in the pad area; and
a plurality of link lines electrically connecting the plurality of pads and the plurality of data lines,
wherein each of the plurality of link lines includes a row-direction link line part extending in a row direction and a column-direction link line part extending in the column direction,
wherein the row-direction link line part included in each of the plurality of link lines is in the active area, and at least a portion of a column-direction link line part included in each of the plurality of link lines is in the active area,
wherein row-direction link line parts included in the plurality of link lines have lengths corresponding to each other.

19. The display panel of claim 18, further comprising:
a plurality of gate lines in the active area, each gate line extending in a row direction;
wherein the row-direction link line part included in each of the plurality of link lines vertically overlaps at least one gate line among the plurality of gate lines,
wherein overlapping areas between the row-direction link line parts included in each of the plurality of link lines and the at least one gate line are equal to each other.

20. The display panel of claim 18, wherein the column-direction link line part includes a same material as the plurality of data lines, and the row-direction link line part includes a different material from the plurality of data lines.
